(19) United States
(12) Patent Application Publication
(10) Pub. No.: US 2002/0068459 A1
(43) Pub. Date: Jun. 6, 2002

(54) Method for etching a semiconductor device

(76) Inventor: Sachie Mochizuki, Chiba-shi (JP)

Correspondence Address: ADAMS & WILKS, ATTORNEYS AND COUNSELORS AT LAW, 31st FLOOR, 50 BROADWAY, NEW YORK, NY, 10004, US

(21) Appl. No.: 09/969,694

(22) Filed: Oct. 3, 2001

(30) Foreign Application Priority Data
Oct. 5, 2000 (JP) 2000-305739

(51) Int. Cl. H01L 21/302; H01L 21/461

(52) U.S. Cl. 438/706; 438/735; 438/738

(57) ABSTRACT

Disclosed is a manufacturing method of a semiconductor device, in which etching of a silicon oxide film is performed using a gaseous phase including hydrofluoric acid. A hard mask made of a compound of Si with C or a compound of Si with N is used to perform etching of a silicon oxide film in a gaseous phase including hydrofluoric acid.

### BACKGROUND OF THE INVENTION

1. Field of the Invention

The present invention relates to a method of manufacturing a semiconductor device, and more particularly to a method of manufacturing a semiconductor device in which silicon oxide films are etched using a gaseous phase including hydrofluoric acid.

2. Description of the Related Art

Hitherto, silicon oxide films have been etched using a liquid phase including hydrofluoric acid with a protective film being an organic resist.

In the conventional etching method described above, etching is performed in a liquid phase. Therefore, parts of the etching portion of the silicon oxide film remains unetched, as shown in FIG. 3A, due to dust, bubbles, or the like existing in the liquid phase, thereby being difficult to finely process the silicon oxide film with the conventional etching method.

Also, an etchant in a gaseous phase including hydrofluoric acid permeates through an organic resist film, with the result that portions masked with the organic resist film are also etched as shown in FIG. 3B. This means that it is impossible to perform the etching using hydrofluoric acid in a gaseous phase.

### SUMMARY OF THE INVENTION

It is an object of the present invention to provide a method of manufacturing a semiconductor device in which etching of silicon oxide film is performed using a gaseous phase including hydrofluoric acid.

The present invention is characterized in that when etching of the silicon oxide film is performed in a gaseous phase including hydrofluoric acid, a hard mask made of a compound of Si with C or a compound of Si with N is used as an alternative to an organic resist by utilizing their properties of being impermeable to an etchant existing in the gaseous phase including the hydrofluoric acid.

The usage of such a hard mask made of a compound of Si with C or a compound of Si with N makes it possible to perform etching in a gaseous phase including hydrofluoric acid. As a result, it becomes possible to finely process the silicon oxide film and to eliminate unetched part of an etching target portion of the silicon oxide film resulting from dust, bubbles, or the like existing in an etching atmosphere.

### BRIEF DESCRIPTION OF THE DRAWINGS

In the accompanying drawings:

FIGS. 1A to 1F are cross-sectional views illustrating a manufacturing method of a semiconductor device in accordance with a first embodiment of the present invention, in which steps of the manufacturing method being shown in order;

FIGS. 2A to 2C are cross-sectional views illustrating a manufacturing method of a semiconductor device in accordance with a second embodiment of the present invention, in which steps of the manufacturing method being shown in order; and

FIGS. 3A and 3B are cross-sectional views illustrating an example of a conventional manufacturing method of a semiconductor device.

### DETAILED DESCRIPTION OF THE PREFERRED EMBODIMENT

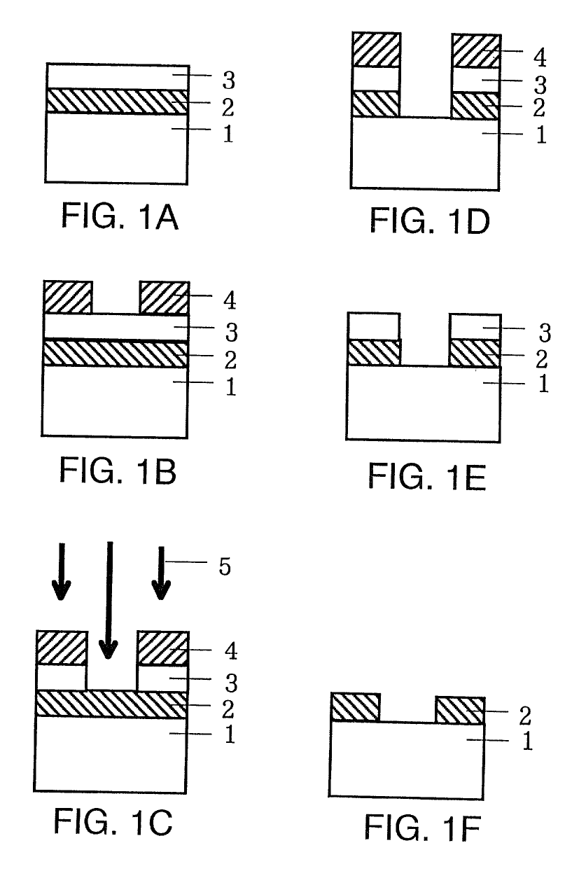

A first embodiment of the present invention will be described below with reference to FIG. 1A to 1F.

As shown in FIG. 1A, a hard mask 3 is formed on a silicon oxide film 2 formed on a semiconductor substrate 1. The hard mask 3 is formed using a film that has property of being etched by hydrofluoric acid at a lower speed than the silicon oxide and being impermeable to a gaseous phase including hydrofluoric acid. For instance, an SiC film or an SiN film formed by chemical vapor deposition (CVD) is used as the hard mask 3.

Next, as shown in FIG. 1B, a patterned resist film 4 is formed on the hard mask 3 and etching of the hard mask 3 is performed. Then, as shown in FIG. 1C, etching of the silicon oxide film 2 is performed using the hard mask 3 in a gaseous phase 5 including the hydrofluoric acid.

Consequently, as shown in FIG. 11D, the silicon oxide film 2 can be etched using the gaseous phase including the hydrofluoric acid. The processes following the etching operation are performed under any one of the conditions shown in FIG. 1D to 1F. FIG. 1D shows a condition in which the resist film 4 is not peeled off, FIG. 1E shows a condition in which the resist film 4 is peeled off, but the hard mask 3 is left on the silicon oxide 2 as an insulating film and a shock absorbing film, and FIG. 1F shows a condition in which the hard mask 3 as well as the resist film 4 are peeled off.

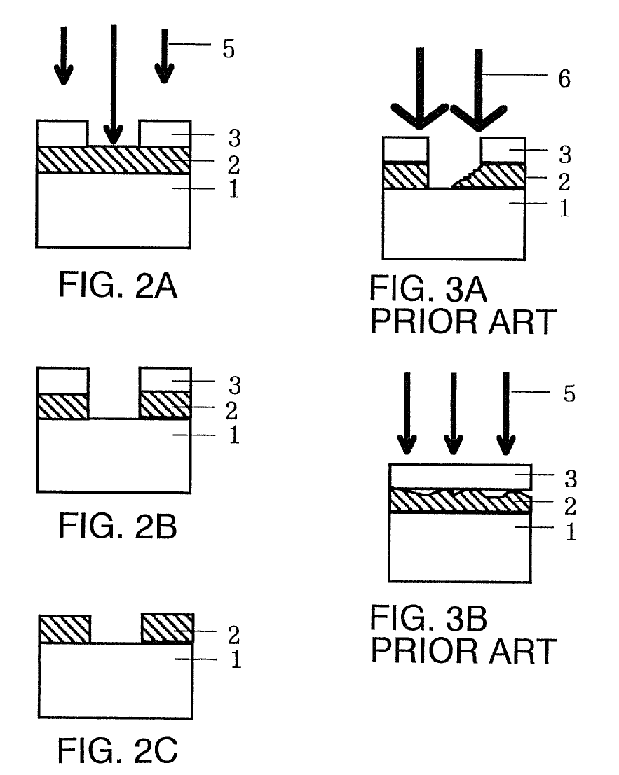

A second embodiment of the present invention will be described below with reference to FIGS. 2A to 2C.

Similarly to the first embodiment, the hard mask 3 is formed on the silicon oxide film 2. Then, the hard mask 3 is etched using the resist film 4 subjected to patterning.

Thereafter, as shown in FIG. 2A, the resist film 4 is peeled off and the etching of the silicon oxide film 2 is performed. The processes following the etching operation are performed under any one of the conditions shown in FIGS. 2B and 2C. FIG. 2B shows a condition in which the hard mask 3 is left on the silicon oxide film 2, whereas FIG. 2C shows a condition in which the hard mask 3 is peeled off.

As described above, according to the present invention, a hard mask is formed using a compound of Si with C or a compound of Si with N. The usage of the hard mask makes it possible to perform etching using a gaseous phase in which the hydrofluoric acid is included. This solves the problem in that with the conventional etching method using a liquid phase including the hydrofluoric acid, part of an etching target portion remains unetched due to dust, bubbles, or the like existing in the liquid phase. That is, it becomes possible to finely perform etching without leaving such unetched part.

What is claimed is:

1. A method for etching a semiconductor device, comprising the steps of: forming a hard mask on the surface of a silicon oxide formed on a semiconductor substrate, forming a resist film on a portion of the surface of the hard mask, etching the had mask, and etching the silicon oxide using a gaseous phase including hydrofluoric acid.

2. A method for etching a semiconductor device according to claim 1, wherein the hard mask has a lower etching rate to the silicon oxide film.

3. A method for etching a semiconductor device according to claim 1, wherein the hard mask is formed using one of a compound of Si with C and a compound of Si with N.
